(19) United States
(12) Patent Application Publication
(10) Pub. No.: US 2024/0193329 A1
(43) Pub. Date: Jun. 13, 2024

(54) CAD DEVICE WITH UTILITY ELEMENT ROUTING AND RELATED METHODS

(71) Applicant: AUGMENTA, INC., TORONTO, ONTARIO (CA)

(72) Inventors: LAWSON FULTON, TORONTO, ONTARIO (CA); CHIARA PIACENTINI, TORONTO, ONTARIO (CA); ALI BARADARAN HASHEMI, TORONTO, ONTARIO (CA); ALEXANDER JOHN ASHBOURNE, TORONTO, ONTARIO (CA); TASSO KARKANIS, TORONTO, ONTARIO (CA); FRANCESCO IORIO, TORONTO, ONTARIO (CA)

(21) Appl. No.: 18/554,519

(22) PCT Filed: Apr. 7, 2022
(86) PCT No.: PCT/CA2022/050535

§ 371 Date: Oct. 9, 2023

Related U.S. Application Data
(60) Provisional application No. 63/171,702, filed on Apr. 7, 2021.

(51) Int. Cl. G06F 30/27; G06F 30/13

(52) U.S. Cl. CPC G06F 30/27; G06F 30/13

(57) ABSTRACT

A CAD device may include a memory configured to store a database having CAD elements, and rules. The CAD device may include a processor coupled to the memory and configured to generate utility element routes for a CAD file based upon a model for routing and the rules, each utility element route having one or more CAD elements from the database, and display the utility element routes with the CAD file.

### RELATED APPLICATION

This application is based upon prior filed copending Application No. 63/171,702 filed Apr. 7, 2021, the entire subject matter of which is incorporated herein by reference in its entirety.

### TECHNICAL FIELD

The present disclosure relates to the field of architectural design, and, more particularly, to computer-aided design for architectural plans and related methods.

### BACKGROUND

Modern building construction is a well-planned enterprise, and the proverbial map is the architectural drawing or architectural plan. In the 1800s, the architectural drawing evolved into blueprints, which allowed for easy reproduction of copies. The architectural drawing for a modern building is complex, including structural elements, and several utilities. Indeed, for a simple single family home, the architectural drawing may comprise 20 or more detailed large format pages.

Of course, the architectural drawing for a high rise building or a large industrial installation geometrically grows the complexity. In fact, for high rises, there can be millions of structural elements. With the advent of computer-aided design (CAD) system, these complicated designs are rendered digitally in three dimensions (3D) and are stored in a CAD file. Moreover, typical CAD files include structural data and Mechanical/Electrical/Plumbing (MEP) data (i.e. the routing of MEP services within the design).

### SUMMARY

Generally, a CAD device may include a memory configured to store a database comprising a plurality of CAD elements, and a plurality of rules (e.g. routing rules, grouping rules, spacing rules, and regulatory rules). The CAD device may include a processor coupled to the memory and configured to generate a plurality of utility element routes for a CAD file based upon a model for routing and the plurality of rules. Each utility element route may include at least one CAD element from the database. The processor may be configured to display the plurality of utility element routes with the CAD file.

In particular, the processor may be configured to generate the model for routing comprising a reinforcement learning model, generate a plurality of agents for the reinforcement learning model, each agent being associated with a point-to-point route, and generate a reward function based upon violation of the plurality of rules. The processor may be configured to generate the reward function based upon a plurality of evaluation values. The plurality of evaluation values may comprise a cost value and a complexity value.

In some embodiments, the processor may be configured to generate the model for routing comprising a supervised learning model based upon a plurality of input values, and a plurality of output values. The plurality of input values may comprise supportability values, complexity values, and dimension values, and the plurality of output values may comprise a cost value, and a maintenance value. The processor may be configured to generate the model for routing based upon a plurality of hyper-parameters. The plurality of hyper-parameters may comprise a branching coefficient and a bending coefficient, for example.

Also, the CAD file may comprise a plurality of elements, and the processor may be configured to process the plurality of elements to generate a plurality of geometric shapes, each geometric shape having associated metadata values, for example. The processor may be configured to execute a graph-based search pathfinding algorithm to find a shortest path in the plurality of geometric shapes. The processor may be configured to combine a subset of the plurality of utility element routes into a single utility element route. For example, the plurality of utility element routes may comprise a plumbing route, an electrical route, and a mechanical route.

Another aspect is directed to a method for operating a CAD device. The method may include storing a database comprising a plurality of CAD elements, and a plurality of rules, and generating a plurality of utility element routes for a CAD file based upon a model for routing and the plurality of rules. Each utility element route may comprise at least one CAD element from the database. The method may include displaying the plurality of utility element routes with the CAD file.

### BRIEF DESCRIPTION OF THE DRAWINGS

FIG. 1 is a schematic diagram of a first example embodiment of a CAD system, according to the present disclosure.

FIG. 2 is a schematic diagram of a second example embodiment of a CAD system, according to the present disclosure.

### DETAILED DESCRIPTION

CAD architectural drawings are typical for construction projects. Nevertheless, the design engineer must generally place and design each element in the architectural drawing manually. More so, when inserting routing for utilities, such as MEP, or processes, such as industrial distribution/piping, the design engineer must balance many concerns, such as code compliance, cost to build, and cost of maintenance, let alone finding the space to route such utilities.

Design engineers manually input the routes each utility subsystem needs to take separately while evaluating the requirements that each subsystem has to satisfy and verifying adherence to regulatory standards using a combination of experience and rule-checking software tools. This manual process may be time consuming, and may restrict the ability to evaluate multiple options and therefore find optimal approaches.

In medium to large projects, a large portion of the design time is spent resolving coordination issues between the utilities subsystems and design tradeoffs. Additionally, requirements change throughout a project lifecycle, such as devices that need plumbing routed to them, devices that need power and control, ventilation requirements per room, operating parameters of industrial motors and electrical devices, etc. With the current design processes, responding to changes can be time consuming and costly during design stages. Designing MEP and industrial distribution/piping systems is therefore a complex, challenging and time consuming process.

The present disclosure may provide an approach to this issue with existing technologies. In particular, the present disclosure may leverage machine learning techniques to automatically route one or more utilities in the CAD architectural drawing. The present disclosure may provide a multi-stage constrained optimization system implemented as a distributed, cloud-based, generative design system, for example.

The present disclosure will now be described more fully hereinafter with reference to the accompanying drawings, in which several embodiments of the invention are shown. This present disclosure may, however, be embodied in many different forms and should not be construed as limited to the embodiments set forth herein. Rather, these embodiments are provided so that this disclosure will be thorough and complete, and will fully convey the scope of the present disclosure to those skilled in the art. Like numbers refer to like elements throughout, and base 100 reference numerals are used to indicate similar elements in alternative embodiments.

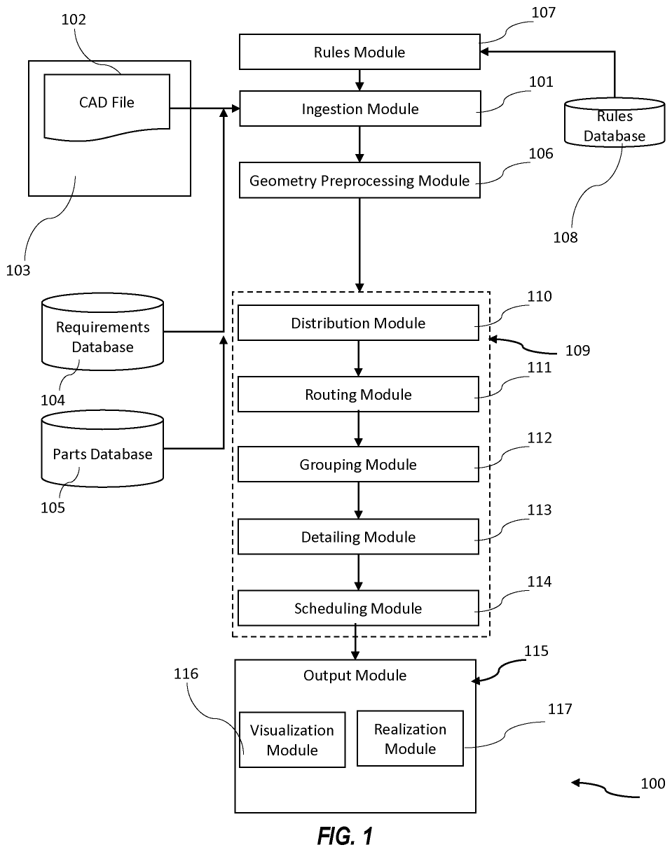

Referring initially to FIG. 1, a CAD system 100 according to the present disclosure is now described. In particular, the CAD system 100 illustratively includes an ingestion module 101 configured to ingest a CAD file 102 with a building design. The CAD file 102 may render the building design and potential utilities elements within CAD software, which may be local or cloud hosted.

The ingestion module 101 is configured to determine system requirements for the building design. The system requirements comprise a collection of spatial constraints and relevant information pertaining to the utility system being designed. The information involves both a complete set of system requirements, but also pre-existing portions of a solution that the system must preserve when generating new solutions. In other words, some of the utilities have been predesigned and can no longer be changed. This characteristic is intended to allow the CAD system 100 to be used when new information unavailable at design time (e.g. location of unmovable structural elements a system would clash with) requires design modifications of a partially constructed system/construction schedule (i.e. change orders).

The information set is obtained from two data sources. The first data source comprises a CAD integration module 103, which comprises a suite of tools that runs directly within a host CAD application as a software add-in. The software add-in enables configuration of spatial constraints that influence the routing and placing of the systems. In this configuration, the CAD project file houses all or part of the necessary system requirements information. When preparing a project for routing design generation, the software add-in identifies all relevant geometry and associated building information modeling (BIM) information required for routing. The CAD integration module 103 is configured to export this data and upload it to cloud storage before beginning the geometric preprocessing component discussed herein. In other embodiments, the CAD file 102 may be uploaded to the CAD system 100 outside of a typical CAD software interface.

In some embodiments, the CAD system 100 may operate without a standalone host CAD application. For example, the CAD system 100 may be configured to provide CAD application features natively (e.g. within the cloud infrastructure or remote server), and provide the spatial and non-spatial constraints and rules for subsequent routing via the native CAD application features.

The second data source comprises a requirements database 104 providing remaining system requirements information necessary to determine the sizing and specifications of the system. This requirements database 104 is retrieved from an existing, external database using an application programming interface (API). In some embodiments, the requirements database 104 may be integrated and accessed internally. In this embodiment, the user can access the requirements database 104 using a dedicated user interface.

The CAD system 100 illustratively includes a parts database 105 configured to store a plurality of CAD elements. The plurality of CAD elements comprises, for example, a collection of available system parts, including metadata such as 3D models, manufacturer unique identifier, price, labor rate, etc. Portions of this data, which may change more frequently, or vary from one project to another (e.g., price, regulatory compliance, etc.), may be stored in a separate database, or retrieved from referenced external data sources to facilitate more frequent updating.

The CAD system 100 illustratively includes a geometry preprocessing module 106 configured to generate a model for routing based upon the CAD file 102 and the plurality of CAD elements. In particular, the geometry preprocessing module 106 is configured to translate geometric project information, such as structural, process and trade geometry, BIM information, point cloud data, and routing zones, into a unified format usable by the CAD system 100.

The input of the geometry preprocessing module 106 includes geometric shapes representing each element in the site model, along with information about the type and material of each element. Additionally, the input includes meshes (e.g. triangle meshes) that represent areas of the site which need to be aligned along non-standard reference axes. The site-meshes are converted to specialized data structures for efficient spatial queries, such as dense uniform grids storing several values, including signed or unsigned distance fields (SDF), as well as information about what kind of support structures can be used at each location on the site.

In other embodiments, other data structures may be used to store this data, such as sparse grids based on different spatial partitioning schemes (e.g. octree). Queries on these data structures are not only related to the type of support structures, but more generally on the volumes where specific rules/constraints are applicable, for efficient queries and updates as the generation process proceeds.

The CAD system 100 illustratively includes a rules module 107 (i.e. a constraint management system module) configured to access a plurality of rules. In some embodiments, the plurality of rules are stored within the rules module 107, but in the illustrated embodiment, the CAD system includes a rules database 108 configured to store the plurality of rules. In particular, the rules module 107 is configured to allow users to specify the constraints that will be applied during the routing generation process. These constraints originate from many sources, such as government-mandated local industry rules and regulations, industry best practices, and client specifications. Rules can be applied to specific portions/areas of the site, called scopes. In some embodiments, once all the information relative to system requirements is collected, the project data is uploaded to cloud storage, followed by a request to the distributed task execution system to initiate the design generation pipeline (DGP). The DGP includes routing, grouping, detailing, scheduling and an optimization module 109.

The CAD system 100 illustratively comprises a distribution module 110. The distribution module 110 is configured to perform selection and allocation of fundamental system distribution components that are required to satisfy the system requirements, based on the requirements specified at a system's endpoints.

The CAD system 100 illustratively comprises a routing module 111 configured to generate one or more utility element routes for the CAD file 102 based upon the model for routing and the plurality of rules. The routing module 111 is configured to generate the one or more utility element routes for the CAD file 102 either sequentially or concurrently (i.e. in parallel). For example, each utility element route may comprise a plumbing route, an electrical route, or a mechanical route (i.e. MEP routes). As discussed herein, each utility element route may comprise a large number of varying individual parts, such as piping, wire conduits, ducts, and other active components.

In some embodiments, a subset of the one or more utility element routes for the CAD file 102 may be unchangeable or locked by a user due to design requirements. The routing module 111 is configured to generate one or more utility element routes for movable utility element routes while keeping the subset locked. For example, in some applications, there may be a utility element route that is required by a client. Here, the routing module 111 would begin with the required route in place and find solutions for connecting utility element routes.

Of course, the utility element route may also comprise other utility services, such as power supply and distribution, information and telecommunications systems, control systems, security and access systems, detection and alarm systems, interior and exterior lighting, heating and cooling, waste water removal, potable cold and hot water supply, water recovery and treatment systems, rainwater, surface and subsurface water drainage, fuel gas piping, industrial water circuits, hydraulic systems, other liquids (e.g. Oil, Hydrogen, liquefied petroleum gas, other chemicals), industrial compressed air, industrial vacuum, other gases (e.g. CO2, Helium, Oxygen, etc.), ventilation/climate control, exhaust gases, and extreme/specialized climate control.

The geometry preprocessing module 106 is configured to send the data structures to the routing module 111. The routing module 111 is configured to perform a search process to find appropriate areas of the site to route the systems through, based on a set of process hyper-parameters, such as branching coefficient and bending coefficient, for example. Of course, the hyper-parameters may comprise additional hyper-parameters. The set of process hyper-parameters define a parametric space for the routing module 111. The routing module 111 is configured to additionally identify portions of the system that can be segmented and extracted for off-site prefabrication/assembly, such as continuous portions of straight, pooled piping.

In some embodiments, the user may influence the routing module 111 at a high level, by providing information about specific areas of the sites (zones) that the routing module should always route through (must-route zone), may optionally route through even if the zone contains solid walls (may-route zone), and avoid routing through at all costs (no-route zone). Also, the routing module 111 may be configured to incorporate parameters that influence the designs to be more assembly-friendly.

The CAD system 100 illustratively comprises a grouping module 112 configured to calculate the appropriate size of utility elements and programmatically aggregate multiple routes together, when multiple subsystems can be transported by a single carrier. In other words, if a subset of the utility element routes can be consolidated into one route, the grouping module 112 is configured to do so.

The CAD system 100 illustratively comprises a detailing module 113 configured to spatially arrange routes into system segments, which can be exhaustively determined, including specific couplings, fittings, and necessary structural supports. The detailing module 113 is configured to also use information from the routing module 111 to separately generate the portions of the system that have been identified as to be prefabricated/assembled off-site. The CAD system 100 also comprises a scheduling module 114 configured to generate a complete work schedule based on specific construction order requirements, aiming to minimize overall construction time and necessary resources. In the illustrated embodiment, the optimization module 109 encompasses the distribution module 110, the routing module 111, the grouping module 112, the detailing module 113, and the scheduling module 114.

The CAD system 100 illustratively comprises an output module 115 configured to display the one or more utility element routes with the CAD file 102. In some embodiments, the output module 115 comprises a visualization module 116 configured to generate visualization and comparison of multiple alternative solutions to a MEP system design problem, and a realization module 117 configured to output a design solution to an external CAD tool and/or a database, or to merge the utility design into an existing external CAD tool database.

In some embodiments, the CAD system 100 may comprise an evaluator module having a set of components that evaluate individual designs, producing scalar or vector values, such as material cost, construction cost, construction time, construction requirements, and maintainability. In short, the evaluator module is configured to quantify performance aspects of the utility design and/or the building design of the CAD file 102. The CAD system 100 may also comprise an optimization module configured to perform multi-objective optimization over the parametric space noted hereinabove, according to one or more evaluation criteria provided by the evaluator module.

The CAD system 100 uses a constrained, multi-stage optimization workflow to produce large amounts of diverse, reliable training data. Machine learning is then used to train multiple models to accelerate the solution of design problems. In particular, reinforcement learning (RL) is used to accelerate the constrained solution generation in the routing module 111, the grouping module 112, and the detailing module 113.

More specifically, the RL model will use agents that represent the task of the routing module 111, which is finding appropriate solutions for the multi-routing problem. Each agent can be responsible for a single point-to-point route and concurrently generates a portion of each route. The state space for each agent at each time step comprises: the end point for its own route, the partial route solution: information about all other partially generated routes: and the entire site geometry. The decision space is what part to pick next (e.g. a straight pipe, a bend, and a pull point), the part configuration (e.g. length of a pipe, the degree of a bend), the opportunity to merge its route with another agent, and the opportunity to split a common route from a pool of agents. The reward function is a combination of the satisfaction or violation of constraints and the other evaluators (i.e. cost, build time, etc.). For example, the internal representation of the decision making model is a Deep Convolutional Neural Network. This system provides a surrogate model for the entire design generation procedure as well, which helps the outer global optimization process to sample more efficiently.

Deep learning is used to substitute components in the evaluator module with surrogate models for evaluation of individual designs. One example is the maintainability evaluator. The computational evaluator for maintainability samples the geometry using techniques, such as ray tracing to calculate reachability, overall height and other factors to calculate an overall score. The machine learning evaluator uses a 3D Convolutional Neural Network to evaluate portions of the design and assign a score based on the recognizable features. The input comprises 3D voxelized geometry with labels describing the type of geometry present in each voxel, and the output is a single real-valued score. The training dataset is generated using the computational evaluator, plus additional user-specified information.

In some embodiments, the CAD system 100 can provide a multi-disciplinary system design by using multiple modules at the same time, for example to concurrently design a mechanical and electrical system, or a full mechanical, electrical and plumbing. In other embodiments, the CAD system 100 can operate on individual systems only (i.e. rendering only electrical, only mechanical, or plumbing).

It should be appreciated that the geometry preprocessing module 106, the rules module 107, the distribution module 110, the routing module 111, the grouping module 112, the detailing module 113, the scheduling module 114, and the output module 115 may all be deployed in one single standalone computing device or a plurality of standalone computing devices. In other embodiments, these modules may all be deployed in a cloud computing platform (CCP), such as Amazon Web Services, Google Cloud Platform, or Microsoft Azure.

In applications where the routing is performed remotely, and the CAD software is executed on a local computing device, the CAD software may operate in conjunction with a plugin software conduit to the remote system. In particular, the ingestion module 101 and output modules 115 may be part of the plugin software conduit.

In the following, the method for generating electrical utility element routes in the CAD system 100 is described in greater detail. More specifically, the ingestion module 101 is configured to generate the system requirements. The system requirements may include electrical system requirements details, such as full electrical schematic system diagram (e.g. as part of a process flow diagram (PFD) or a piping and instrumentation diagram (P&ID)), site areas available for electrical rooms, sources and loads, such as tags, motors horsepower, starter type, and voltage and wiring specifications.

The parts database 105 illustratively includes a collection of all electrical and mechanical parts available to the generative design system to use, such as portions of conduits, cable trays, fasteners, couplings, fittings, switches, and support structures. The rules module 107 is configured to derive constraints and rules encoded from applicable local legal regulations, such as, for example, the National Electrical Code (NEC), and supplement with additional ones extracted from industry best practices and common client requirements.

The distribution module 110 is configured to select and allocate Motor Control Centers (MCCs) and Programmable Logic Controllers (PLCs) in racks to control the entire electrical system based on the devices that require powering/control. Racks are configured, and space is allocated in electrical rooms. Electrical rooms are located appropriately on the site. The distribution module 110 is also responsible for allocating routing endpoints (e.g. light fixtures), and transition points, for example, between underground and above ground, and between in-wall/slab and out of wall/slab.

The routing module 111 is configured to execute a graph-based search pathfinding algorithm (e.g. A*) to find the shortest paths in the discretized grid generated by the geometric preprocessor. As part of the A pathfinding task, the routing module 111 can use ML models to estimate the cost function between points on the graph/grid and to provide an estimation of the value of each graph/grid point relative to the destination of a route. In one embodiment, a Manhattan distance is used as an approximation of remaining distance/cost to destination.

In some embodiments, a 3D CNN that uses a coarse representation of the site geometry and overall site complexity as input may provide a better estimate considering the presence of coarse obstacles and routable/supportable areas. Inputs of the model may comprise: for each grid point, a supportability type, a SDF value, a number of cables routed, and site dimensions, etc. The outputs of the model may comprise: a part/construction cost value, and a maintainability score value. The training set for this model can be generated synthetically using the conventional computational pipeline using a variety of test sites. In some embodiments, the solution generation may be similar to the RL techniques described hereinabove.

Paths may source from the MCCs and the PLCs and terminate to positions of electrical devices anywhere in the site. A SDF representing the site structural characteristics and optionally mechanical and plumbing characteristics is provided by the geometry preprocessing module 106 and annotated with supportability information, so the routing module 111 chooses paths that can be supported. The routing module 111 is configured to select one device to route at the time, and run the pathfinder algorithm in sequential fashion. In other embodiments, the routing module 111 is configured to route one or more devices concurrently with the pathfinder algorithm. All paths are combined together into a set of connected segments called raceway segments, defined as bounding boxes containing the same cables. Each raceway segment is annotated with all the constraints that components should respect.

The grouping module 112 is configured to determine the size of cables and relative raceways, and assign sets of devices and their required cables into groups that will share a raceway. The objective of the grouping module 112 is to minimize the project cost, adhere to NEC rules, adhere to user-set constraints, and create solutions that are feasible to install. First, conductors are split into mutually exclusive sets such that conductors in each set are allowed to share a raceway with any conductor in the same set and not with any of the other sets. Then, for each set of conductors, an optimization algorithm finds the optimal grouping of conductors that minimizes the cost. To evaluate the cost of a grouping, the size of conductors and raceway segments are determined according to the related constraints.

The detailing module 113 is configured to assemble racks of raceway from generic component families inside the raceway segments. The detailing module 113 is configured to determine an ideal arrangement of raceways in a segment, called a compartment layout. The compartment comprises a subsection of raceways in the segment that can be grouped together. The detailing module 113 is configured to place all necessary fittings, including couplings, unions, conduit bodies, and elbows, and then place supports along the length of the raceway network, attaching to surrounding geometry in the model.

The compartment layout determines the disposition of the conduits and trays inside the same rack. The position of raceways is chosen to avoid collisions when they leave the rack and to fit inside the available space. In particular, for fitting placement, once the raceway segments have been given a layout, the geometry of the segments and compartment layouts is analyzed. Parts (e.g. conduit stick, conduit bodies, trays) are chosen, sized, and placed considering user-defined and electrical code constraints. Topological relationships between the parts are explicitly represented during this phase.

In particular, for support placement, the first step in support placement is to identify the locations for each support. Supports need to be placed according to building and electrical code, and to user-defined constraints, for example, before and after each bend, as well as be placed a minimum of X feet apart where X is a user-configurable parameter. Once a support location is chosen, the particular type of support to be placed is decided, such as a “Trapeze”, “Floorstand”, “Standoff”, etc. For example, the particular type of support is decided from a support specification, which is a priority list of supports where each type of support is compatible with certain scenarios, such as vertical versus horizontal running racks.

Finally, once the support type and location have been chosen, the support itself can be placed. Each type of support has its own parametric model, which takes as input the location, orientation, and segment/compartments that it will support. These parametric models are then used to compute specific locations and translation for each component within the support, such as the rods, nuts, bolts, cross members, etc. Each of these components is then output to the output module 115.

The detailing module 113 is configured to account for different constraints sets enforced in different locations of a site, for example, rules and constraints may vary across the site to adhere to specific hazard requirements. The scheduling module 114 is configured to define the full set of construction tasks required to assemble the electrical system, estimate the time and resources required to complete each task, and enforce construction order dependencies that limit the number of tasks that can be performed concurrently. The evaluator module may provide metrics, such as, for example, cable pulling tension, cable bending tension, material cost, construction cost, construction time, maintainability.

In the following, the method for generating plumbing utility element routes in the CAD system 100 is described in greater detail. It should be appreciated that features from the above described method for generating electrical utility element routes may be incorporated into this method. The system requirements may comprise plumbing system requirements details, such as full plumbing schematic system diagram (e.g. a PFD or a P&ID), locations of main fluid/gas reservoirs, type/s of fluid/gas being transported, required flow characteristics (i.e. pressure, flow rate) and locations of sources and sinks, thermal requirements for pipe network thermal expansion/contraction, and vibration profiles for system fatigue analysis.

The parts database 105 illustratively includes all mechanical parts available to the generative design system to use, such as portions of pipe, valves, flow regulators, and pumps. The rules module 107 is configured to derive constraints and rules encoded from the Uniform Plumbing Code (UPC), and supplement with additional ones extracted from industry best practices and common client requirements. The distribution module 110 is configured to locate pumps, size sinks, select and allocate in the site, and group into mechanical rooms. Mechanical rooms are located appropriately on the site.

The routing module 111 is configured to execute a graph-based search pathfinding algorithm to find the shortest paths in the discretized grid generated by the geometry preprocessing module 106. Piping paths may originate from specific sources and terminate at designated sinks anywhere in the site. An SDF representing the site structural characteristics and optionally mechanical and electrical characteristics is provided by the geometry preprocessing module 106 and annotated with supportability information, so the routing module 111 chooses paths that can be supported. The routing module 111 may be configured to select one duct to route at the time and runs the pathfinder algorithm in sequential fashion, or to select multiple routes in parallel or concurrently.

In some embodiments, some of the routes comprise “in-slab” or “in-wall” conduit routing immersed into concrete structures. In-slab and in-wall routing of plumbing systems entail the positioning of portions of flexible conduit inside the rebar armature of concrete structures, before concrete is poured into casts. Flexible conduit allows more freedom in positioning, relative to rigid conduit, although it subtracts space/volume from solid concrete material, which weaken the reinforced concrete structure. An additional engineering requirement is therefore introduced, and at no point in the slab, the density of conduit per unit of volume can exceed a given threshold. The particular case necessitates a dedicated form of routing and associated data structures. Therefore, a method that represents flexible conduits with spline curves, and the interior volume of a concrete slab with a 3D density function represented as a uniform sparse grid. The routing mechanism places splines to connect all endpoints for conduit that go through the slab, then assigns to each grid cell a density value proportional to the amount and size of conduit that intersect that cell. An optimization procedure proceeds to move the splines control points to ensure density of conduit at any point in the grid exceeds the threshold value.

In other embodiments, the routing module 111 is configured to route one or more ducts concurrently with the pathfinder algorithm. Ducts may be aggregated into a tree of larger capacity ducts and/or combined together into a set of connected duct segments, defined as bounding boxes continuing the same duct. Each segment is annotated with all the constraints that components should respect.

For this application, the grouping module 112 calculates the correct sizing of the pipes in the utility system to ensure appropriate flow rates are achieved. The detailing module 113 is configured to assemble racks of pipes from generic component families into segments, where necessary. The system determines an ideal arrangement of pipes in a segment, called a compartment layout. The detailing module 113 then places all necessary fittings, including couplings, unions, pipes and elbows. The detailing module 113 then places appropriate supports along the length of the pipe network, attaching to surrounding geometry in the model.

The compartment layout determines the disposition of the pipes and trays inside the same rack. The position of the plumbing system is chosen to avoid collisions when they branch from the rack and to fit inside the available space. With regards to fitting placement, once the segments have been given a layout, the geometry of the segments and compartment layouts is analyzed. Parts (e.g. pipes, trays) are chosen, sized, and placed considering user-defined and plumbing code constraints. Topological relationships between the parts are explicitly represented during this phase. With regards to support placement, the first step in support placement is to identify the locations for each support. Supports need to be placed at regular intervals and before and after each junction. Once a support location is chosen, the particular type of support to be placed is decided such as a “Trapeze”, “Floorstand”, “Standoff”, etc. The particular type of support is decided from a support specification, which is a priority list of supports where each type of support is compatible with certain scenarios, such as vertical versus horizontal running racks.

Finally, once the support type and location have been chosen, the support itself can be placed. Each type of support has its own parametric model, which takes as input the location, orientation, and segment/compartments that it will support. These parametric models then compute specific locations and translation for each component within the support, such as the rods, nuts, bolts, cross members, etc. Each of these components is then output to the realization module 117. The detailing module 113 is configured to account for different constraints sets enforced in different locations on a site, for example, rules and constraints may vary across the site to adhere to specific hazard requirements.

The scheduling module 114 is configured to define the full set of construction tasks required to assemble the plumbing system, estimate the time and resources required to complete each task, and enforce construction order dependencies that limit the number of tasks that can be performed concurrently. The evaluator module may provide metrics, such as, for example, interior flow computational fluid dynamics for pressure drop, thermomechanical analysis, material cost, construction cost, construction time, and maintainability.

Machine learning may be used as a surrogate model of the Computational Fluid Dynamics (CFD) and thermal simulation. For example, the structure of the topology and critical dimensions of the duct system can be encoded as a graph neural network, and trained with an appropriate dataset generated by conventional CFD and thermal analysis. The dataset would contain tuples as follows: as input data the graph structure of the HVAC system and a vector of boundary conditions (e.g. temperature and pressure on the system inlets, at the output of air-handling units): and as output data the corresponding readings of temperature and pressure at all system outlets, pre-evaluated using CFD and thermal simulation.

In the following, the method for generating mechanical (e.g. airflow mechanical) utility element routes in the CAD system 100 is described in greater detail. It should be appreciated that features from the above described method for generating electrical utility element routes and the above described method for generating plumbing utility element routes may be incorporated into this method, and vice versa. The system requirements may include full heating, ventilation, and air conditioning (HVAC) schematic system diagram, heating and cooling loads, locations of furnaces, air filtration, humidification and dehumidification units, and air conditioners, required flow characteristics (pressure, flow rate), and locations of intakes, outlets, registers and diffusers.

The parts database 105 illustratively includes all mechanical parts available to the generative design system to use, such as portions of ducts, fans, blowers, preheaters, furnaces, chillers, dampers, intakes, and outlets. The rules module 107 is configured to derive constraints and rules encoded from the ASHRAE Standard 90.1, and supplement with additional ones extracted from industry best practices and common client requirements. The distribution module 110 is configured to locate furnaces, preheaters, heaters, chillers, blowers are sized, selected and allocated in the site and grouped into mechanical rooms. Mechanical rooms are located appropriately on the site.

The routing module 111 is configured to route duct paths sourced from the mechanical rooms and terminate at designated areas anywhere in the site. A SDF representing the site structural characteristics and optionally plumbing and electrical characteristics is provided by the geometry preprocessing module 106 and annotated with supportability information, so the routing module 111 chooses paths that can be supported. The routing module 111 is configured to select one duct to route at the time (alternatively concurrently or in parallel), and run the pathfinder algorithm. Ducts may be aggregated into a tree of larger capacity ducts and/or combined together into a set of connected duct segments, defined as bounding boxes continuing the same duct. Each segment is annotated with all the constraints that components should respect.

For this application, the grouping module 112 calculates the correct sizing of the ducts in the utility system to ensure appropriate airflows are achieved. The detailing module 113 is configured to assemble racks of ducting from generic component families into segments, where necessary. The detailing module 113 is configured to determine an ideal arrangement of ducts in a segment, called a compartment layout. The detailing module 113 is configured to then place all necessary fittings, including couplings, unions, and elbows. The detailing module 113 is configured to then place appropriate supports along the length of the pipe network, attaching to surrounding geometry in the model.

The compartment layout determines the disposition of the ducts and trays inside the same rack. The position of the ducts system is chosen to avoid collisions when they branch from the rack and to fit inside the available space. With regards to fitting placement, once the segments have been given a layout, the geometry of the segments and compartment layouts is analyzed. Parts (e.g. ducts, exhausts) are chosen, sized, and placed considering user-defined and mechanical code constraints. Topological relationships between the parts are explicitly represented during this phase. With regards to support placement, the first step in support placement is to identify the locations for each support. Supports need to be placed at regular intervals and before and after each junction. Once a support location is chosen, the particular type of support to be placed is decided, such as a “Trapeze”, etc. The particular type of support is decided from a support specification, which is a priority list of supports where each type of support is compatible with certain scenarios such as vertical vs horizontal running racks.

Finally, once the support type and location have been chosen, the support itself can be placed. Each type of support has its own parametric model which takes as input the location, orientation, and segment/compartments that it will support. These parametric models then compute specific locations and translation for each component within the support, such as the rods, nuts, bolts, cross members, etc. Each of these components is then output to the realization module 117.

The detailing module 113 is configured to also account for different constraints sets enforced in different locations on a site, for example, rules and constraints may vary across the site to adhere to specific hazard requirements. The scheduling module 114 is configured to define the full set of construction tasks required to assemble the HVAC system, estimate the time and resources required to complete each task, and enforce construction order dependencies that limit the number of tasks that can be performed concurrently. The evaluator module may provide metrics, such as, for example, computational fluid dynamics for pressure drop, air flow, thermomechanical analysis, material cost, construction cost, construction time, and maintainability.

It should be appreciated that the features and machine learning concepts applied to any of the above described routing applications (i.e. mechanical utility routing, electrical utility routing, and plumbing utility routing) is equally applicable to the other routing applications. Moreover, the features of any of the disclosed embodiments herein may be combined with other embodiments.

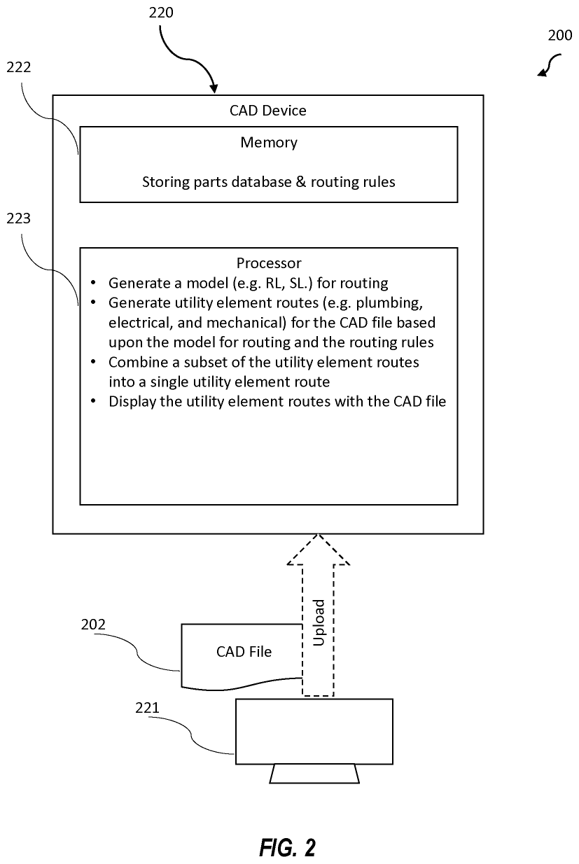

Referring now additionally to FIG. 2, another embodiment of the CAD system 200 is now described. In this embodiment of the CAD system 200, those elements already discussed above with respect to FIG. 1 are incremented by 100 and most require no further discussion herein. It should be appreciated that any feature from the above described CAD system 100 can be integrated with the CAD system 200.

This CAD system 200 illustratively includes a CAD device 220, and a computing device 221 in communication with the CAD device over a network (not shown, e.g. local area network or the Internet). The computing device 221 illustratively includes a personal computing device, but may comprise a mobile computing device or a tablet computing device, for example.

In the illustrated embodiment, the computing device 221 is configured to upload a CAD file 202 to the CAD device 220 for subsequent processing. Also, in this embodiment, the CAD device 220 is configured to operate native CAD software for rendering and viewing the CAD file 202. The visual output of the rendering of the CAD file 202 is transmitted to the computing device 221 for display on a local display device.

In other embodiments (See FIG. 1), the computing device 221 is configured to execute the CAD software locally, and upload the CAD file 202 to the CAD device 220 for processing. The computing device 221 may execute a plugin associated with local CAD software in communication with the CAD device 220.

The CAD device 220 illustratively includes a memory 222 configured to store a database comprising a plurality of CAD elements, and a plurality of rules. In particular, the plurality of rules may comprise routing rules, grouping rules, spacing rules, and regulatory rules (e.g. rules that describe compliant MEP systems, according to standard engineering codes, such as NEC, ASHRAE). The CAD device 220 illustratively includes a processor 223 coupled to the memory 222 and configured to generate a model for routing based upon at least the plurality of rules.

The model for routing may comprise a machine learning model in some embodiments. Further, the machine learning model may be trained using example routing instances initially relying upon the plurality of rules, for example, a supervised learning process.

In some embodiments, the CAD device 220 comprises a standalone computing device, such as a server device. In other embodiments, the CAD device 220 may comprise resources on a cloud computing platform. The processor 223 is configured to generate a plurality of utility element routes for the CAD file 202 based upon the model for routing and the plurality of rules. Each utility element route comprises at least one CAD element from the database. In other words, the processor 223 is configured to use the parts bin from the database to complete the utility element route from point-to-point, as detailed herein above. The processor 223 is configured to display the plurality of utility element routes with the CAD file 202 on the computing device 221.

In particular, the processor 223 is configured to generate the machine learning model comprising a RL model, generate a plurality of agents for the reinforcement learning model, each agent being associated with a point-to-point route, and generate a reward function based upon violation of the plurality of rules. The processor 223 is configured to generate the reward function based upon a plurality of evaluation values. The plurality of evaluation values comprises a cost value and a complexity value, for example.

In some embodiments, the processor 223 is configured to generate the machine learning model comprising a supervised learning model based upon a plurality of input values, and a plurality of output values. The plurality of input values comprises supportability values, complexity values, and dimension values, for example. The plurality of output values comprises a cost value, and a maintenance value, for example. The processor 223 is configured to generate the machine learning model for routing based upon a plurality of hyper-parameters. For example, in some embodiments, the plurality of hyper-parameters comprises a branching coefficient and a bending coefficient.

Also, the CAD file 202 comprises a plurality of elements. In some embodiments, the processor 223 is configured to process the plurality of elements to generate a plurality of geometric shapes, each geometric shape having associated metadata values (e.g. material characteristics, shape identification characteristics such as “wall”, “column”, “floor”, and other such data). For example, the plurality of geometric shapes may comprise a plurality of triangle meshes. In other embodiments, this information can be represented by other CAD/BIM data formats (i.e. according to the Industry Foundation Classes standard), which the system can also use as representation of the site geometry.

The processor 223 is configured to execute a graph-based search pathfinding algorithm (e.g. A*) to find a shortest path in the plurality of geometric shapes. The processor 223 is configured to combine a subset of the plurality of utility element routes into a single utility element route. For example, the plurality of utility element routes may comprise a plumbing route, an electrical route, and a mechanical route.

Another aspect is directed to a method for operating a CAD device 220. The method includes storing a database comprising a plurality of CAD elements, and a plurality of rules, and generating a machine learning model for routing based upon a CAD file 202 and the plurality of CAD elements. The method further comprises generating a plurality of utility element routes for the CAD file 202 based upon the machine learning model for routing and the plurality of rules, each utility element route comprising at least one CAD element from the database, and displaying the plurality of utility element routes with the CAD file.

Many modifications and other embodiments of the present disclosure will come to the mind of one skilled in the art having the benefit of the teachings presented in the foregoing descriptions and the associated drawings. Therefore, it is understood that the present disclosure is not to be limited to the specific embodiments disclosed, and that modifications and embodiments are intended to be included within the scope of the appended claims.

1. A computer-aided design (CAD) device comprising:
a memory configured to store a database comprising a plurality of CAD elements, and a plurality of rules; and
a processor coupled to the memory and configured to
generate a plurality of utility element routes for a CAD file based upon a model for routing and the plurality of rules, each utility element route comprising at least one CAD element from the database, and
display the plurality of utility element routes with the CAD file.

2. The CAD device of claim 1 wherein the processor is configured to generate the model for routing comprising a reinforcement learning model, generate a plurality of agents for the reinforcement learning model, each agent being associated with a point-to-point route, and generate a reward function based upon violation of the plurality of rules.

3. The CAD device of claim 2 wherein the processor is configured to generate the reward function based upon a plurality of evaluation values, the plurality of evaluation values comprising a cost value and a complexity value.

4. The CAD device of claim 1 wherein the processor is configured to generate the model for routing comprising a supervised learning model based upon a plurality of input values, and a plurality of output values: wherein the plurality of input values comprises supportability values, complexity values, and dimension values; and wherein the plurality of output values comprises a cost value, and a maintenance value.

5. The CAD device of claim 1 wherein the processor is configured to generate the model for routing based upon a plurality of hyper-parameters, the plurality of hyper-parameters comprising a branching coefficient and a bending coefficient.

6. The CAD device of claim 1 wherein the CAD file comprises a plurality of elements; and wherein the processor is configured to process the plurality of elements to generate a plurality of geometric shapes, each geometric shape having associated metadata values.

7. The CAD device of claim 6 wherein the processor is configured to execute a graph-based search pathfinding algorithm to find a shortest path in the plurality of geometric shapes.

8. The CAD device of claim 1 wherein the processor is configured to combine a subset of the plurality of utility element routes into a single utility element route.

9. The CAD device of claim 1 wherein the plurality of utility element routes comprises a plumbing route, an electrical route, and a mechanical route.

10. A computer-aided design (CAD) device comprising:
a memory configured to store a database comprising a plurality of CAD elements, and a plurality of rules; and
a processor coupled to the memory and configured to
generate a machine learning model for routing based upon a CAD file and the plurality of CAD elements, the machine learning model comprising a reinforcement learning model,
generate a plurality of agents for the reinforcement learning model, each agent being associated with a point-to-point route,
generate a reward function based upon violation of the plurality of rules,
generate a plurality of utility element routes for the CAD file based upon the machine learning model for routing and the plurality of rules, each utility element route comprising at least one CAD element from the database, and
combine a subset of the plurality of utility element routes into a single utility element route.

11. The CAD device of claim 10 wherein the processor is configured to generate the reward function based upon a plurality of evaluation values, the plurality of evaluation values comprising a cost value and a complexity value.

12. The CAD device of claim 10 wherein the processor is configured to generate the machine learning model comprising a supervised learning model based upon a plurality of input values, and a plurality of output values: wherein the plurality of input values comprises supportability values, complexity values, and dimension values; and wherein the plurality of output values comprises a cost value, and a maintenance value.

13. The CAD device of claim 10 wherein the processor is configured to generate the machine learning model for routing based upon a plurality of hyper-parameters, the plurality of hyper-parameters comprising a branching coefficient and a bending coefficient.

14. The CAD device of claim 10 wherein the CAD file comprises a plurality of elements; and wherein the processor is configured to process the plurality of elements to generate a plurality of geometric shapes, each geometric shape having associated metadata values.

15. The CAD device of claim 14 wherein the processor is configured to execute a graph-based search pathfinding algorithm to find a shortest path in the plurality of geometric shapes.

16. The CAD device of claim 10 wherein the plurality of utility element routes comprises a plumbing route, an electrical route, and a mechanical route.

17. A method for operating a computer-aided design (CAD) device, the method comprising:
storing a database comprising a plurality of CAD elements, and a plurality of rules:
generating a plurality of utility element routes for a CAD file based upon a model for routing and the plurality of rules, each utility element route comprising at least one CAD element from the database; and
displaying the plurality of utility element routes with the CAD file.

18. The method of claim 17 further comprising generating the model for routing comprising a reinforcement learning model, generate a plurality of agents for the reinforcement learning model, each agent being associated with a point-to-point route, and generate a reward function based upon violation of the plurality of rules.

19. The method of claim 18 further comprising generating the reward function based upon a plurality of evaluation values, the plurality of evaluation values comprising a cost value and a complexity value.

20. The method of claim 17 further comprising generating the model for routing comprising a supervised learning model based upon a plurality of input values, and a plurality of output values; wherein the plurality of input values comprises supportability values, complexity values, and dimension values; and wherein the plurality of output values comprises a cost value, and a maintenance value.
